(19) United States
(12) Patent Application Publication
(10) Pub. No.: US 2002/0075025 A1
(43) Pub. Date: Jun. 20, 2002

(54) Semiconductor testing tool

(76) Inventor: Masahiro Tanaka, Tokyo (JP)

Correspondence Address: MCDERMOTT WILL & EMERY, 600 13TH STREET, N.W., WASHINGTON, DC, 20005-3096, US

(21) Appl. No.: 09/568,537

(22) Filed: May 11, 2000

(30) Foreign Application Priority Data
Jun. 30, 1999 (JP) 11-185167

(51) Int. Cl. G01R 31/26

(52) U.S. Cl. 324/765

(57) ABSTRACT

A semiconductor testing tool, formed with a reduced number of structural elements and allowing a high frequency test, comprising a multi-layer substrate 3 in which internal lead wires 8 are embedded, through holes formed in the multi-layer substrate 3, contact pins 6 inserted in the through holes so as to contact directly with solder balls and a silicon rubber 5 provided at a rear side of the multi-layer substrate 3 to absorb a scattering in height of the contact pins 6.

### BACKGROUND OF THE INVENTION

1. Field of the Invention

The present invention relates to a semiconductor testing tool usable for a finally selecting step in the manufacturing of semiconductors.

2. Discussion of Background

Devices such as BGA, CSP or the like, having solder balls as contactors are subjected to testing in a finally selecting step wherein various kinds of contactors such as a pogo pin type, a pinch type or a leaf spring type are used.

FIG. 7 is a cross-sectional view showing a pogo pin type semiconductor testing tool, wherein reference numeral 11 designates a device, numeral 12 a pogo pin, numeral 13 a socket, numeral 14 a multi-layer substrate, numeral 15 a cable and numeral 16 a through hole.

FIG. 8 is a cross-sectional view showing a leaf spring type semiconductor testing tool wherein reference numeral 17 designates a device, numeral 18 a leaf spring, numeral 19 a socket, numeral 20 a multi-layer substrate, numeral 21 a cable and numeral 22 a through hole.

FIG. 9 is a cross-sectional view showing a pinching type semiconductor testing tool wherein reference numeral 23 designates a device, numeral 24 a pinching member, numeral 25 a socket, numeral 26 a multi-layer substrate, numeral 27 a cable and numeral 28 a through hole.

In the conventional semiconductor testing tools having the above-mentioned constructions, when a high frequency test is conducted to a device, the length of contact pins affects largely the quality of the test. In the pinching type test or the leaf spring type test, although they are economical, the length of the contact pins can not be reduced because the tools of such type require a sufficient elasticity. Accordingly, it is impossible to conduct high speed testing.

In the pogo pin type, although it is possible to reduce the length by changing the structure, the pogo pin type is expensive and the change of the structure largely affects cost for testing. Further, since the socket has a mechanism for holding the contact pins, the number of structural elements is large and therefore, cost for the socket is increased.

### SUMMARY OF THE INVENTION

It is an object of the present invention to provide a semiconductor testing tool capable of reducing the number of structural elements by employing a structure that contact pins are received in the multi-layer substrate, hence, it is inexpensive, and suitable for high frequency testing.

In accordance with a first aspect of the present invention, there is provided a semiconductor testing tool which comprises a multi-layer substrate in which internal leading wires are embedded, contact pins inserted in a contacting state in through holes formed in the multi-layer substrate and an elastic member provided below the multi-layer substrate to absorb a scattering in height of each of the contact pins.

According to a second aspect of the present invention, there is provided the semiconductor testing tool according to the first aspect, wherein a lower portion of the contact pins is cut obliquely from a side.

According to a third aspect of the present invention, there is provided the semiconductor testing tool according to the first aspect, wherein the contact pins have a two stage structure comprising a large diameter portion and a small diameter portion.

In accordance with a fourth aspect of the present invention, there is provided a semiconductor testing tool which comprises a multi-layer substrate in which internal lead wires are embedded and spring members inserted in through holes formed in the multi-layer substrate.

According to a fifth aspect of the present invention, there is provided the semiconductor testing tool according to the fourth aspect, wherein the spring members have a two stage structure comprising a large diameter portion and a small diameter portion.

### BRIEF DESCRIPTION OF THE DRAWING

A more complete appreciation of the invention and many of the attendant advantages thereof will be readily obtained as the same becomes better understood by reference to the following detailed description when considered in connection with the accompanying drawings, wherein:

FIG. 1 is a cross-sectional view showing the semiconductor testing tool according to a first embodiment of the present invention;

FIG. 2 is an enlarged view of a part A in FIG. 1:

FIG. 3 is a cross-sectional view of the semiconductor testing tool according to a second embodiment of the present invention;

FIG. 4 is a cross-sectional view of the semiconductor testing tool according to a third embodiment of the present invention;

FIG. 5 is a cross-sectional view of the semiconductor testing tool according to a fourth embodiment of the present invention;

FIG. 6 is a cross-sectional view of the semiconductor testing tool according to a modified form of the fourth embodiment of the present invention;

FIG. 7 is a cross-sectional view of a conventional semiconductor testing tool;

FIG. 8 is a cross-sectional view of a conventional semiconductor testing tool; and

FIG. 9 is a cross-sectional view of a conventional semiconductor testing tool.

### DETAILED DESCRIPTION OF PREFERRED EMBODIMENT

In the following, preferred embodiments of the present invention will be described with reference to the drawings.

Embodiment 1

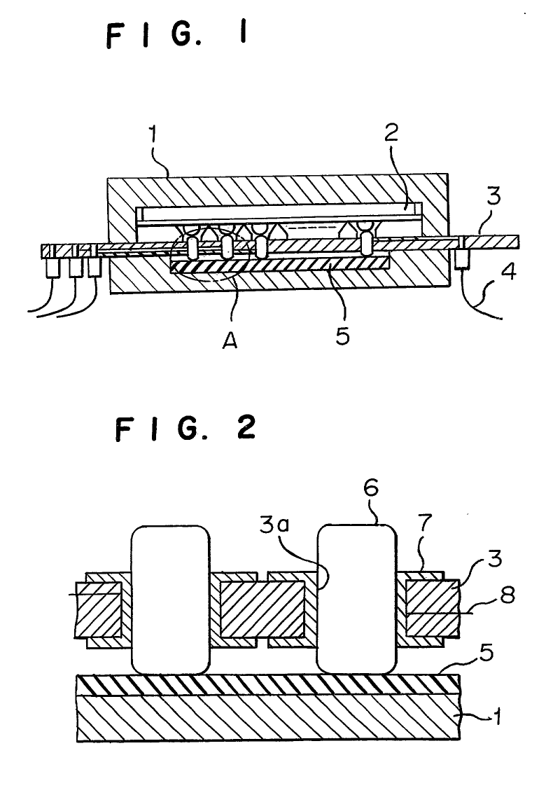

In FIGS. 1 and 2, reference numeral 1 designates a socket casing, numeral 2 a device, numeral 3 a multi-layer substrate, numeral 4 a cable and numeral 5 a silicon rubber. Reference numeral 6 designates a contact pin. The surface of the contact pin 6 is subjected to a gold plate treatment so as to assure reliable contact. Numeral 7 designates a gold plate layer provided between the contact pin 6 and the multi-layer substrate 3. Numeral 8 designates an internal leading wire embedded in the multi-layer substrate 3.

In this embodiment, the multi-layer substrate 3 contains therein an arrangement of wires, and through holes 3a are formed in the multi-layer substrate 3 so that the wires are connectable across each layer of the substrate 3. In this embodiment, the through holes 3a are utilized so as to reduce the distance between the device and the multi-layer substrate 3. In the through holes 3a, the contact pins 6 which contact directly with solder balls are inserted so as to contact an inner wall of the through holes 3a. A silicon rubber 5 as an plastic member is located on an inner surface of the socket casing 1, i.e., at a rear surface side of the multi-layer substrate 3 so that the positions of the contact pins 6 are flexible, whereby a scattering in height of the contact pins 6 and a scattering in height of the solder balls can be absorbed. Since signals for testing pass directly from the contact pins 6 through the multi-layer substrate 3, the shortest electric path is formed, and a high speed testing is obtainable.

Further, the number of structural elements for the each of the contact pins 6 is only one and therefore, the manufacture can be made economically.

Embodiment 2

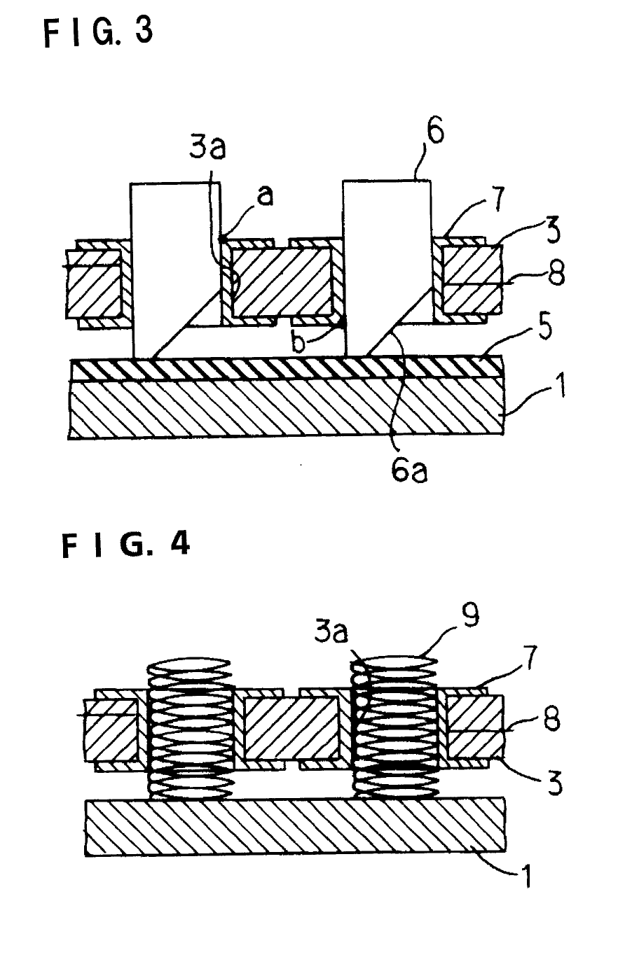

This embodiment aims at improving stability of contact by modifying the shape of each of the contact pins 6 as shown in FIG. 3. Namely, a slant portion 6a is formed by cutting obliquely a lower portion of the contact pin 6 at a side. In this case, since the contact between the contact pins 6 and the through holes 3a is made at a relatively upper portion, the length of electrical paths can be shortened. Further, since each of the contact pins 6 contacts correctly the inner wall of each of the through holes 3a at tow positions a and b, electrical paths can be provided more stably.

Also, the number of structural elements can be reduced in the same manner as in Embodiment 1.

Embodiment 3

In Embodiments 1 and 2, the contact pins 6 themselves have no elastic property and therefore, the elastic member such as the silicon rubber 5 is required. In this embodiment, a spring member 9 which is subjected to a gold plate treatment is used for the contact pin as shown in FIG. 4. With such measures, both functions as a contactor and a spring can be provided. Specifically, the spring member 9 is formed, for example, to have an outer diameter 0.05 mm larger than the diameter of the through hole 3a. When the spring member is forcibly fitted into the through hole 3a, a reliable contact is obtainable between the spring member 9 and the inner wall of the through hole 3a, and a stable electrical path can be maintained. In this embodiment, the silicon rubber is unnecessary whereby the number of structural elements can be reduced. Further, since the spring member is used as a contactor, contact points are increased whereby more stable electrical path is obtainable.

Embodiment 4

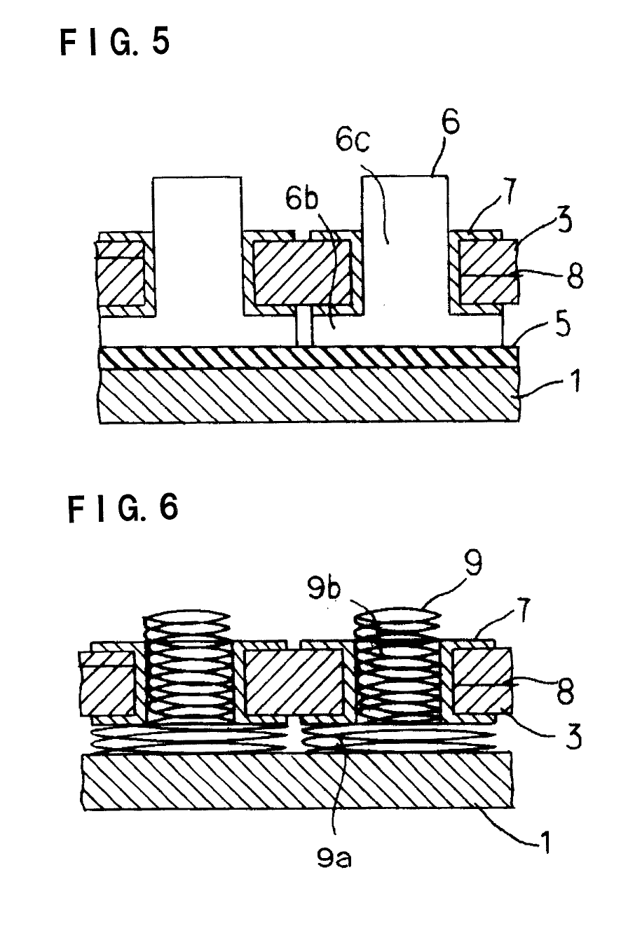

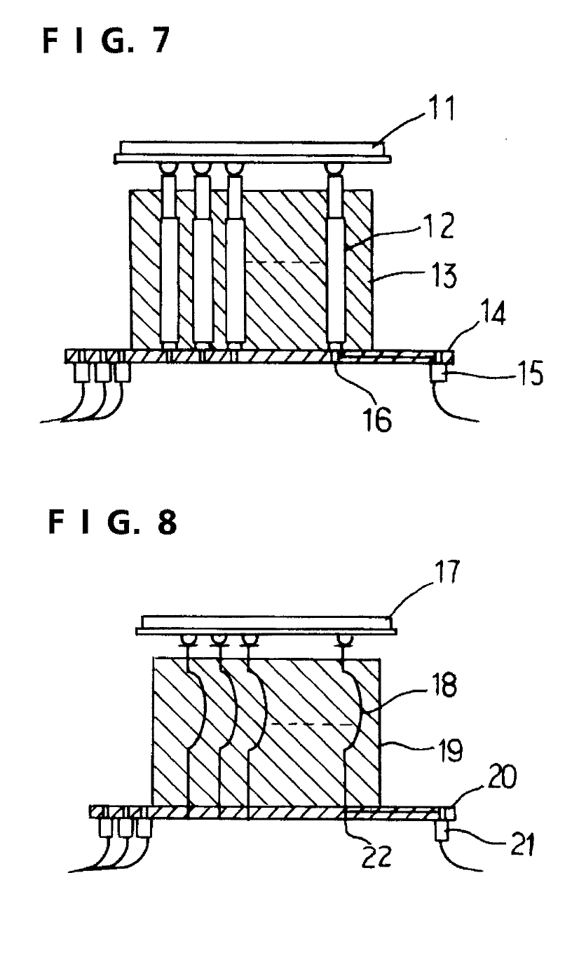

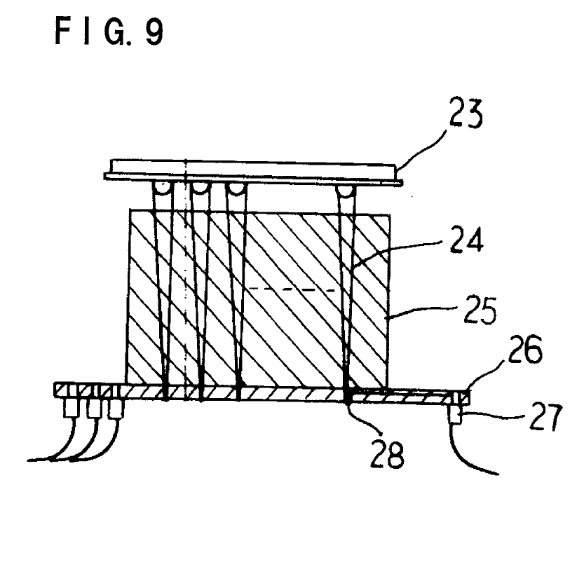

In this embodiment, each of the contact pins 6 has a two stage structure comprising a large diameter portion 6b and a small diameter portion 6c as shown in FIG. 5. The large diameter portion 6b is held between a multi-layer substrate 3 and a silicon rubber 5. Accordingly, the contact property between the contact pins 6 and the multi-layer substrate 3 can be improved.

Embodiment 5

In this embodiment, a spring member 9 is formed to have a two stage structure comprising a large diameter portion 9a and a small diameter portion 9b as shown in FIG. 6. In this case, the contact property between the spring member and the multi-layer substrate can be improved in the same manner as in Embodiment 3.

Obviously, numerous modifications and variations of the present invention are possible in light of the above teachings. It is therefore to be understood that within the scope of the appended claims, the invention may be practiced otherwise than as specifically described herein.

The entire disclosure of Japanese Patent Application JP11-185167 filed on Jun. 30, 1999 including specification, claims, drawings and summary are incorporated herein by reference in its entirety.

What is claimed is:

1. A semiconductor testing tool which comprises a multi-layer substrate in which internal leading wires are embedded, contact pins inserted in a contacting state in through holes formed in the multi-layer substrate and an elastic member provided below the multi-layer substrate to absorb a scattering in height of each of the contact pins.

2. The semiconductor testing tool according to claim 1, wherein a lower portion of the contact pins is cut obliquely at a side.

3. The semiconductor testing tool according to claim 1, wherein the contact pins have a two stage structure comprising a large diameter portion and a small diameter portion.

4. A semiconductor testing tool which comprises a multi-layer substrate in which internal lead wires are embedded and spring members inserted in through holes formed in the multi-layer substrate.

5. The semiconductor testing tool according to claim 4, wherein the spring members have a two stage structure comprising a large diameter portion and a small diameter portion.
